(19) United States
(12) Patent Application Publication
(10) Pub. No.: US 2017/0244021 A1
(43) Pub. Date: Aug. 24, 2017

(54) ACOUSTIC RESONATOR AND METHOD OF MANUFACTURING THE SAME

(71) Applicant: SAMSUNG ELECTRO-MECHANICS CO., LTD., Suwon-si (KR)

(72) Inventors: Won HAN, Suwon-si (KR); Dae Hun JEONG, Suwon-si (KR); Jae Chang LEE, Suwon-si (KR); Tae Yoon KIM, Suwon-si (KR); Moon Chul LEE, Suwon-si (KR)

(73) Assignee: SAMSUNG ELECTRO-MECHANICS CO., LTD., Suwon-si (KR)

(21) Appl. No.: 15/271,483

(22) Filed: Sep. 21, 2016

(30) Foreign Application Priority Data
Feb. 18, 2016 (KR) 10-2016-0018983

(51) Int. Cl. H01L 41/047; H01L 41/29

(52) U.S. Cl. CPC H01L 41/0475; H01L 41/047; H01L 41/29

(57) ABSTRACT

An acoustic resonator includes a resonating part including a piezoelectric layer located on a first electrode and a second electrode located on the piezoelectric layer; and a frame located on the second electrode along an edge of the resonating part, wherein the frame includes an inner surface and an outer surface, and the inner surface includes two inclined surfaces.

### CROSS-REFERENCE TO RELATED APPLICATIONS

This application claims the benefit under 35 USC 119(a) of Korean Patent Application No. 10-2016-0018983 filed on Feb. 18, 2016 in the Korean Intellectual Property Office, the entire disclosure of which is incorporated herein by reference for all purposes.

### BACKGROUND

1. Field

The following description relates to an acoustic resonator. The following description also relates to a method of manufacturing such an acoustic resonator.

2. Description of Related Art

In accordance with the trend of the miniaturization of wireless communications devices, the miniaturization of radio frequency component technology has become actively desirable. An example of the miniaturization of the radio frequency component technology may include a filter having a form of a bulk acoustic wave (BAW) resonator that uses a technology of manufacturing a semiconductor thin film wafer.

A bulk acoustic wave (BAW) resonator is a resonator in which an element having a thin film causes resonance through a piezoelectric dielectric material that is deposited on a silicon wafer, which is a semiconductor substrate, and uses piezoelectric characteristics of the piezoelectric dielectric material, which is implemented as the filter.

Applications of the bulk acoustic wave (BAW) resonator include small and lightweight filters, an oscillator, a resonance element, an acoustic resonance mass sensor, and other applications in mobile communications devices, chemical and biological devices, and other appropriate technological devices.

Meanwhile, investigation into various structural shapes and functions for improving characteristics and performance of BAW resonators has been undertaken. Accordingly, research into various structures and method of manufacturing BAW resonators has also occurred.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, an acoustic resonator includes a resonating part including a piezoelectric layer located on a first electrode and a second electrode located on the piezoelectric layer, and a frame located on the second electrode along an edge of the resonating part, wherein the frame includes an inner surface and an outer surface, and the inner surface includes two inclined surfaces.

Each of the two inclined surfaces may include a distinct angle of inclination.

The inner surface of the frame may include a first inclined surface that extends from the second electrode, and a second inclined surface that extends from the first inclined surface.

An angle of inclination of the first inclined surface may be smaller than an angle of inclination of the second inclined surface.

The outer surface of the frame may be a vertical surface or an inclined surface.

The frame may further include a top surface that connects the second inclined surface and the outer surface to each other.

The frame may include a first frame including the first inclined surface and a second frame including the second inclined surface and located on the first frame.

The frame may be formed of the same material as the second electrode.

The resonating part is formed on a membrane layer and spaced apart from a substrate by an air gap.

The frame may be formed in a ring shape along the edge of the resonating part.

In another general aspect, a method of manufacturing an acoustic resonator includes stacking a first electrode and a piezoelectric layer on a substrate, stacking a conductive layer on the piezoelectric layer, forming a frame layer having two inclined surfaces on the conductive layer, and completing a second electrode and a frame by patterning the frame layer and the conductive layer.

Each of the two inclined surfaces may include a distinct angle of inclination.

The forming of the frame layer may include forming a first frame layer including a first inclined surface on the conductive layer, and forming a second frame layer including a second inclined surface on the first frame layer.

The forming of the frame layer may include forming the first frame layer and the second frame layer by using a lift-off process or a dry etching process.

The completing of the second electrode and the frame may include removing portions of the conductive layer and the frame layer, and reducing thicknesses of the conductive layer and the frame layer located on an outer portion of a resonating part.

The method may further include exposing the first electrode by removing a portion of the piezoelectric layer, and forming a connection electrode on each of the first electrode and the second electrode.

In another general aspect, a method of manufacturing an acoustic resonator includes stacking a first electrode and a piezoelectric layer on a substrate, forming a first frame including a first inclined surface on the piezoelectric layer, forming a second frame including a second inclined surface on the first frame, stacking a conductive layer on the piezoelectric layer, the first frame, and the second frame, and performing a patterning of the conductive layer to form a second electrode and to further form the first and second frames.

Each of the first and second inclined surfaces may include a distinct angle of inclination.

Other features and aspects will be apparent from the following detailed description, the drawings, and the claims.

### BRIEF DESCRIPTION OF DRAWINGS

FIG. 1 is a cross-sectional view of an acoustic resonator according to an example.

FIG. 2 is an enlarged cross-sectional view of part A of the example of FIG. 1.

FIGS. 3 through 9 are views illustrating a method of manufacturing an acoustic resonator according to an example.

FIG. 10 is a cross-sectional view schematically illustrating an acoustic resonator according to another example.

FIGS. 11 through 14 are views illustrating a method of manufacturing an acoustic resonator according to another example.

FIG. 15 is a graph illustrating S-parameter performance of an acoustic resonator according to an example.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

Expressions such as “first conductivity type” and “second conductivity type” as used herein may refer to opposite conductivity types such as N and P conductivity types, and examples described herein using such expressions encompass complementary examples as well. For example, an example in which a first conductivity type is N and a second conductivity type is P encompasses an example in which the first conductivity type is P and the second conductivity type is N.

An aspect of the present disclosure may provide an acoustic resonator with improved performance, and a method of manufacturing the acoustic resonator.

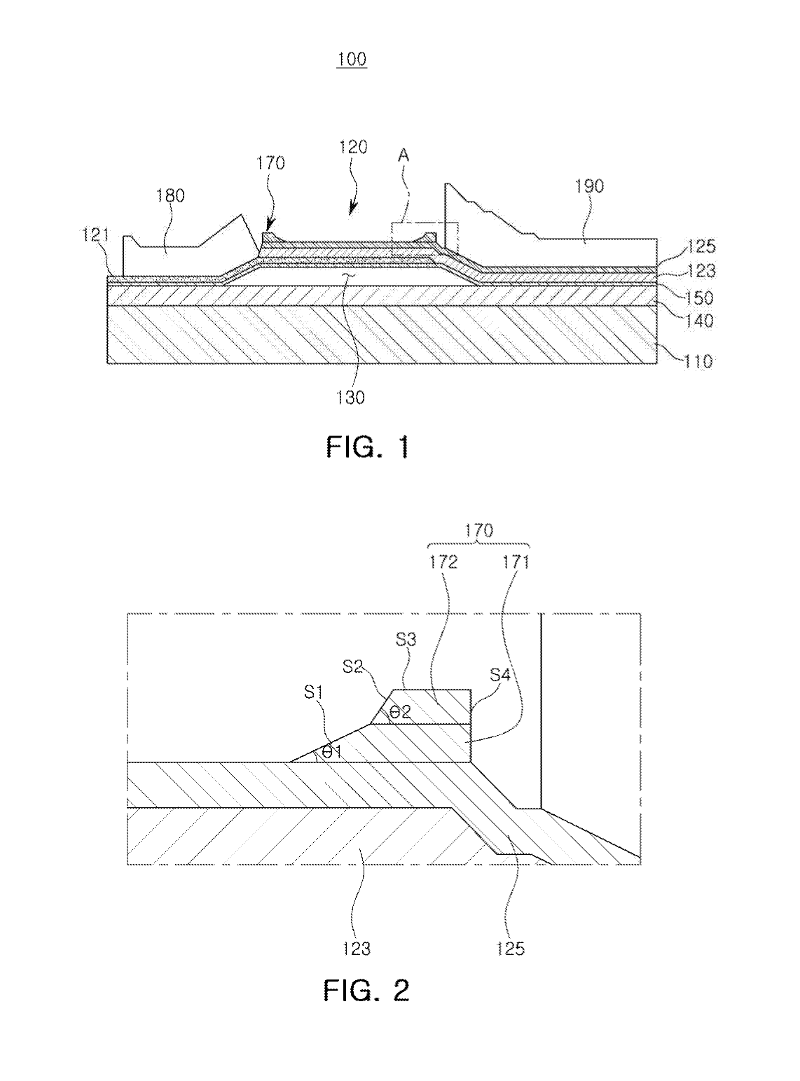

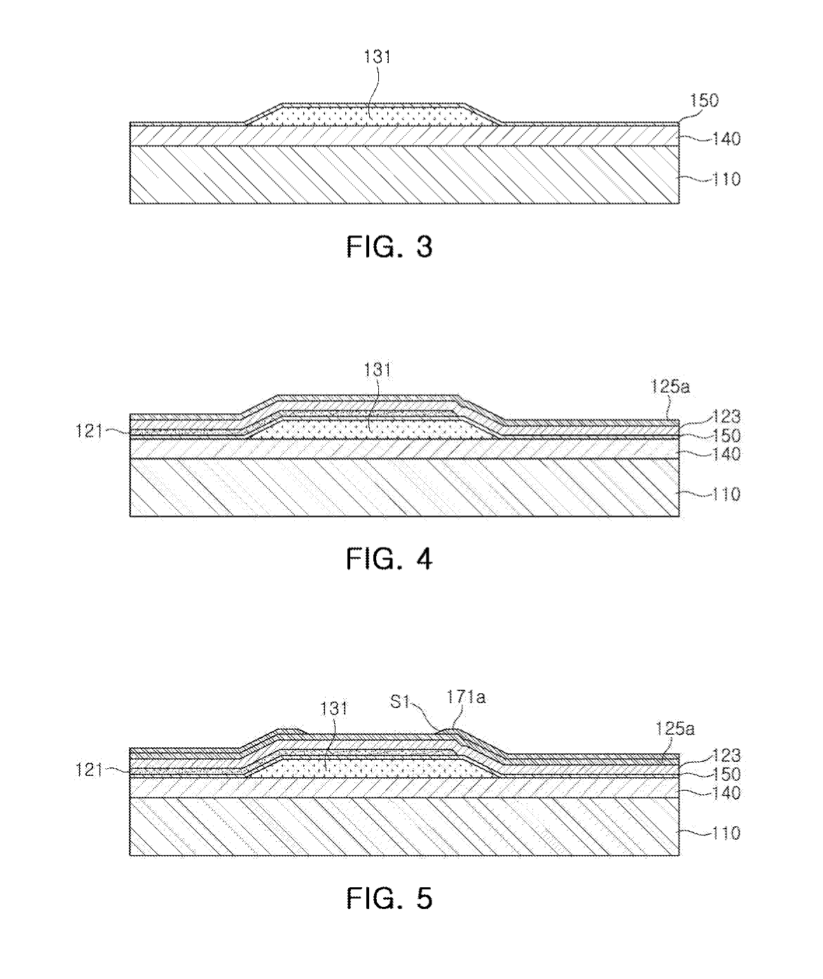

FIG. 1 is a cross-sectional view of an acoustic resonator according to an example. FIG. 2 is an enlarged cross-sectional view of part A of the example of FIG. 1.

Referring to the examples of FIGS. 1 and 2, an acoustic resonator 100 according to an example includes a substrate 110 and a resonating part 120.

An air gap 130 may be formed between the substrate 110 and the resonating part 120. Also, the resonating part 120 may be formed on a membrane layer 150 so as to be spaced apart from the substrate 110 by the air gap 130.

The substrate 110 may be formed as a silicon substrate or as a silicon on insulator (SOI) type substrate.

In the example of FIG. 1, the resonating part 120 may include a first electrode 121, a piezoelectric layer 123, and a second electrode 125. The resonating part 120 may be formed by sequentially stacking the first electrode 121, the piezoelectric layer 123, and the second electrode 125 from below upon one another. Thus, the piezoelectric layer 123 is located between the first electrode 121 and the second electrode 125.

Because the resonating part 120 is formed on the membrane layer 150, the membrane layer 150, the first electrode 121, the piezoelectric layer 123, and the second electrode 125 may be sequentially formed on the substrate 110.

For example, the resonating part 120 may allow the piezoelectric layer 123 to resonate in response to signals applied to the first electrode 121 and the second electrode 125 to generate a resonance frequency and an anti-resonance frequency, respectively.

For example, the first electrode 121 and the second electrode 125 each may be formed of a metal such as gold (Au), molybdenum (Mo), ruthenium (Ru), aluminum (Al), platinum (Pt), titanium (Ti), tungsten (W), palladium (Pd), chromium (Cr), nickel (Ni), or another appropriate similar metal.

The resonating part 120 may use acoustic waves of the piezoelectric layer 123. For example, when the signals are applied to the first electrode 121 and the second electrode 125, mechanical vibration may occur along a thickness direction of the piezoelectric layer 123 so as to generate acoustic waves.

Here, as a material of the piezoelectric layer 123, a material such as zinc oxide (ZnO), aluminum nitride (AlN), quartz, or a similar appropriate material may be used.

A resonance phenomenon of the piezoelectric layer 123 may occur when a half of a wavelength of the applied signal coincides with a thickness of the piezoelectric layer 123. Because electrical impedance is significantly changed when the resonance phenomenon occurs, the acoustic resonator according to an example may be used as a filter capable of selecting a frequency.

For example, the resonating part 120 may be situated so as to be spaced apart from the substrate 110 by the air gap 130 in order to improve a quality factor of the acoustic resonator.

For example, by forming the air gap 130 between the resonating part 120 and the substrate 110, acoustic waves generated by the piezoelectric layer 123 may not be influenced by the substrate 110.

Furthermore, reflective characteristics of acoustic waves generated by the resonating part 120 may be improved by the presence of the air gap 130. Because the air gap 130, which is an empty space, has an impedance value close to infinite, acoustic waves may not be lost in the air gap 130 and may remain in the resonating part 120.

For example, the first electrode 121 and the second electrode 125 may be formed to extend to an outer side of the resonating part 120, and a first connection electrode 180 and a second connection electrode 190 may be connected to each of the extended portions of the first electrode 121 and the second electrode 125.

For example, the first connection electrode 180 and the second connection electrode 190 may be provided to confirm characteristics of the resonator and the filter, and accordingly perform a required frequency trimming. However, the function of the first connection electrode 180 and the second connection electrode 190 is not limited to these examples, and the first connection electrode 180 and the second connection electrode 190 may also provide other appropriate advantageous effects.

Additionally, in the example of FIG. 1, a frame 170 may be situated on the resonating part 120.

For example, the frame 170 may be formed in a ring shape along an edge of the resonating part 120. However, the shape of the frame 170 is not limited to being a ring shape as described, but may also be formed in a shape of a plurality of discontinuous arc shapes.

For example, the acoustic resonator 100 may reflect a horizontal elastic wave that is directed to the outside of the resonating part 120 to the inside of the resonating part 120 using the frame 170, thereby preventing energy loss of an elastic wave. Accordingly, because the reflected horizontal elastic wave reduces the resulting energy loss, the acoustic resonator 100 according to the example of FIG. 1 may secure high Q-factor and kₜ². For example, a Q-factor may refer to a quality factor that characterizes a resonator's bandwidth relative to its center frequency and kₜ² may refer to a coefficient of electromagnetic coupling.

Therefore, the high Q-factor may improve blocking characteristics of other frequency bands in implementing a filter or a duplexer. Furthermore, the high kₜ² may secure a bandwidth to increase transmission quantity and rate of data at the time of transmitting and receiving the data.

In various examples, the frame 170 may be formed of a piezoelectric material, a dielectric material, or a metal. For example, the frame 170 may be formed of a synthetic material having one or more of aluminum nitride (AlN), lead zirconate titanate (PZT), silicon oxide (SiO₂), titanium oxide (TiO₂), ruthenium (Ru), molybdenum (Mo), gold (Au), titanium (Ti), copper (Cu), tungsten (W), and aluminum (Al) as a main component. However, these are only example materials and other materials are used in other examples, as appropriate.

Thus, the frame 170 according to the present example may be formed by forming a frame layer by using a sputtering or depositing process, and then removing an unnecessary portion by using a lift-off process or a dry etching process. Also, the frame 170 may be formed of the same material as the second electrode 125, and may be additionally formed as part of a process of forming the second electrode 125.

In addition, as illustrated in the example of FIG. 2, the frame 170 according to the present example may include inner surfaces S1 and S2, an outer surface S4, and a top surface S3.

In such an example, the inner surfaces S1 and S2 of the frame 170 may include at least two inclined surfaces S1 and S2 having different angles of inclination θ1 and θ2. In this example, when the top surface of the substrate 110 is provided as a horizontal surface, the angles of inclination θ1 and θ2 denote angles formed with the horizontal surface.

Thus, accordingly, the inner surfaces of the frame 170 may be classified as a first inclined surface S1 and a second inclined surface S2. As a result, the inner surfaces of the frame 170 may be classified as a first frame 171 including the first inclined surface S1, and a second frame 172 including the second inclined surface S2.

Thus, the first inclined surface S1 may be an inclined surface that extends from the second electrode 125, and the second inclined surface S2 may extend from the first inclined surface S1 and may be situated to be higher than the first inclined surface S1.

Also, the frame 170 according to the present example may have the angle of inclination θ1 of the first inclined surface S1 formed to be smaller than the angle of inclination θ2 of the second inclined surface S2.

In such an example, the top surface S3 may be situated between the second inclined surface S2 and the outer surface S4, and may be formed as the horizontal surface. However, the top surface S3 is not to be limited to the horizontal surface, and other configurations are possible.

Furthermore, the outer surface S4 of the frame 170 may connect the top surface S3 and the second electrode 125 to each other, and may be formed in a form of a vertical surface or in a form of an inclined surface.

As such, as the frame 170 includes a plurality of inclined surfaces S1 and S2, and as a result, the acoustic resonator 100 according to the present example may provide improved performance over a conventional acoustic resonator.

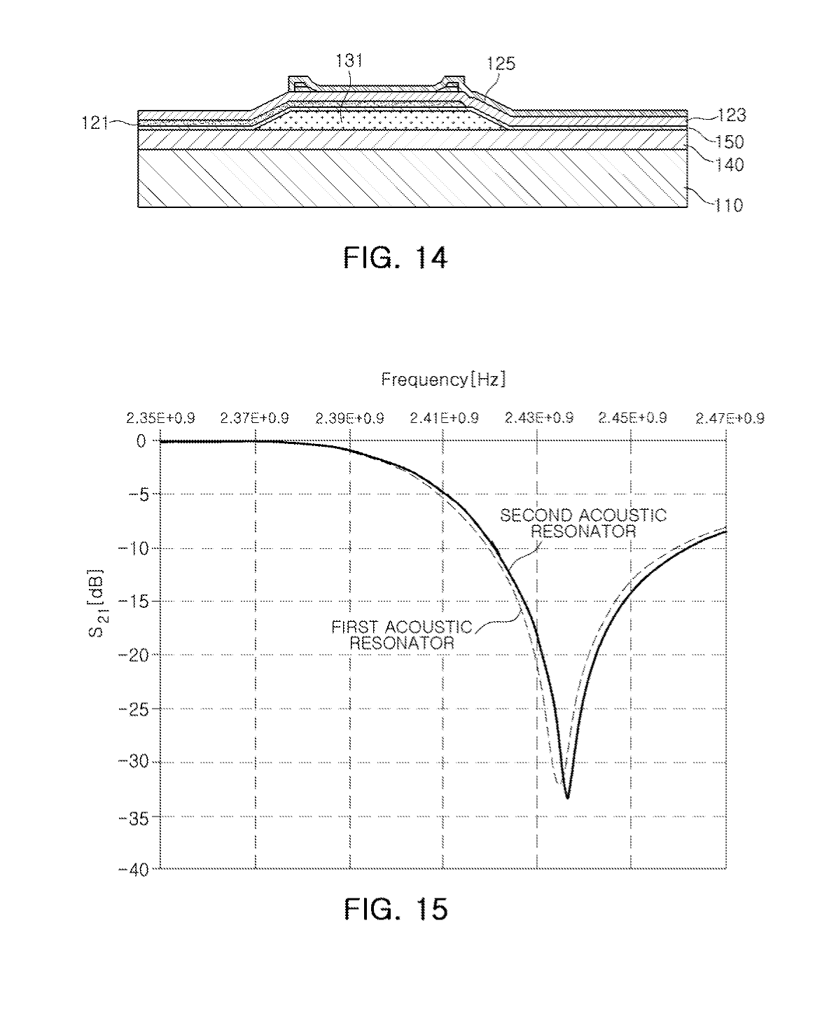

FIG. 15 is a graph illustrating S-parameter performance of an acoustic resonator according to an example, and illustrates all of the S-parameters of an acoustic resonator, that is, a first acoustic resonator having an alternative frame and another acoustic resonator, that is, a second acoustic resonator according to the present example.

In such an example, the conventional frame refers to a frame of which an inner surface is formed as a vertical surface.

Referring to the graph of FIG. 15, it may be seen that the second acoustic resonator according to the present example has improved attenuation, about 1.5 dB, as compared to the first acoustic resonator according to the related art. Further, it was measured in experiments that kₜ² is improved by 0.2%, and Q-factor is improved by 400. As a result, in an example in which the frame 170 according to the present exemplary embodiment is used, it may be seen that higher Q-factor and kₜ² may be secured, and improved performance may be provided accordingly for the acoustic resonator according to an example.

Next, a method of manufacturing an acoustic resonator according to an example is to be described.

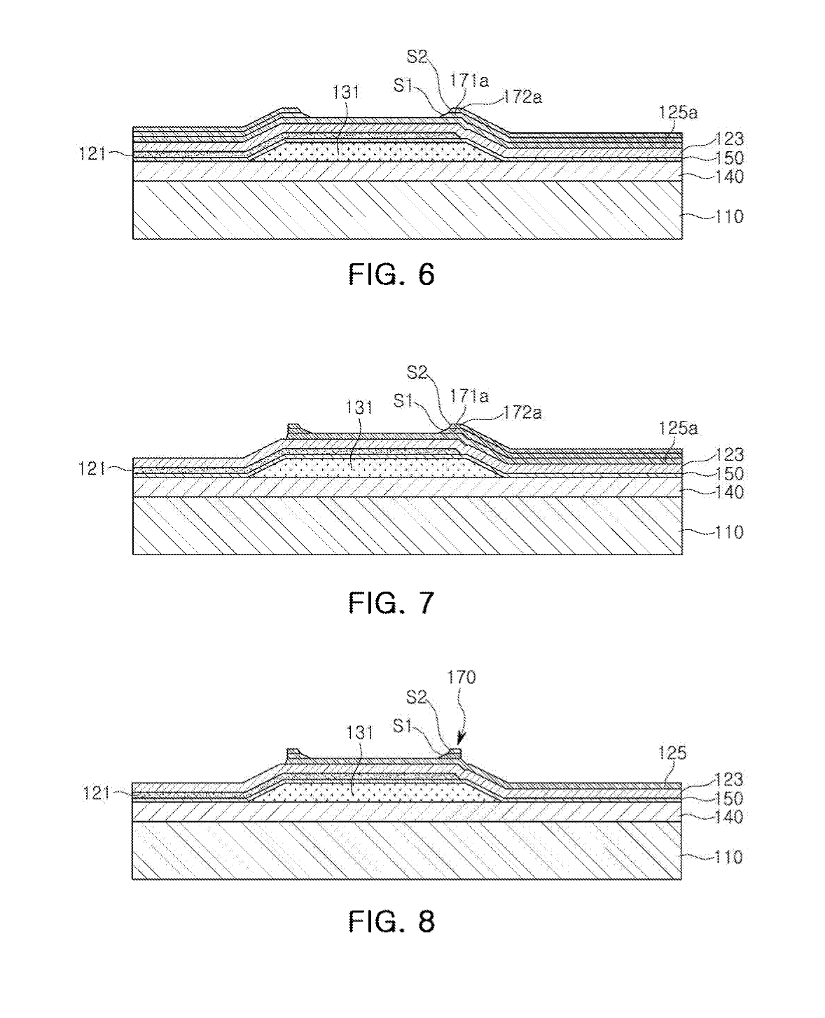

FIGS. 3 through 9 are views illustrating a method of manufacturing an acoustic resonator according to an example.

First, referring to the example of FIG. 3, an etching stop layer 140 may be formed on the substrate 110.

The etching stop layer 140 may serve to protect the substrate 110 when a sacrificial layer 130 is removed to form the air gap 130, as shown in the example of FIG. 1. For example, the etching stop layer 140 may be formed of a silicon oxide film, a silicon nitride film, or the like, but is not limited thereto, and the etching stop layer 140 may be formed of another material.

Next, the sacrificial layer 131 may be formed on the etching stop layer 140.

Such a sacrificial layer 131 may be removed by a later etching process to form the air gap 130, as shown in the FIG. 1. The sacrificial layer 131 may be formed of a material such as polysilicon, a polymer, or the like.

Next, the membrane layer 150 may be formed on the sacrificial layer 131. The membrane layer 150 may be positioned over the air gap 130 to serve to help maintain a shape of the air gap 130 and to help support a structure of the resonating part 120, as shown in the example of FIG. 1.

Next, as illustrated in the example of FIG. 4, the first electrode 121 and the piezoelectric layer 123 may be sequentially formed on the membrane layer 150.

For example, the first electrode 121 may be formed by depositing a conductive layer on the entirety of a top surface of the membrane layer 150 and then removing, for example, by patterning, an unnecessary portion. Furthermore, the piezoelectric layer 123 may be formed by depositing a piezoelectric material on the first electrode 121.

According to the present example, the first electrode 121 may be formed of molybdenum (Mo). However, the material of the first electrode 121 is not limited to such a material, and the first electrode 121 may be formed of various metals such as gold, ruthenium, aluminum, platinum, titanium, tungsten, palladium, chromium, nickel, and other metals, as appropriate.

According to the present example, the piezoelectric layer 123 may be formed of aluminum nitride (AlN). However, the material of the piezoelectric layer 123 is not limited to this particular material, and the piezoelectric layer 123 may also be formed of various other appropriate piezoelectric materials such as zinc oxide (ZnO), quartz, and so on.

Next, as shown in FIG. 4, a conductive layer 125a for forming the second electrode 125 as shown in FIG. 1 may be formed on the piezoelectric layer 123. For example, the conductive layer 125a may be deposited on the entirety of the top surface of the piezoelectric layer 123.

According to the present example, the conductive layer 125a for forming the second electrode 125 may be formed of ruthenium (Ru). However, the material of the conductive layer 125a is not limited to this particular metal, and the conductive layer 125a may also be formed of various other appropriate metals such as gold (Au), molybdenum (Mo), ruthenium (Ru), aluminum (Al), platinum (Pt), titanium (Ti), tungsten (W), palladium (Pd), chromium (Cr), nickel (Ni), and so on.

Next, in order to form the frame 170, as illustrated in the example of FIG. 5, a first frame layer 171a may be formed on the conductive layer 125a.

For example, the first frame layer 171a may be formed by a lift-off process. In such an example, the first frame layer 171a illustrated in FIG. 5 may be implemented by depositing and patterning a photo resist in a region of the resonating part 120 to form a first mask layer, depositing a conductor layer so as to cover the conductive layer 125a and the first mask layer, and then removing the first mask layer.

Meanwhile, alternatively, the first frame layer 171a may also be formed by a dry etching process. For example, the first frame layer 171a may be formed by a process of depositing the conductive layer on the entirety of the region of the resonating part 120, a process of depositing and patterning the photo resist on the conductive layer to form a mask layer, not illustrated, a process of performing dry etching on the conductor layer using the mask layer to complete the first frame layer, and a process of removing the mask layer.

Next, as illustrated in the example of FIG. 6, a second frame layer 172a may be formed on the first frame layer 171a.

The second frame layer 172a may also be formed by the lift-off process. For example, the second frame layer 172a illustrated in the example of FIG. 6 may be implemented by depositing and patterning a photo resist in a region of the resonating part 120 to form a second mask layer, depositing a conductor layer so as to cover all of the first frame layer 171a and the second mask layer, and then removing the second mask layer.

Meanwhile, alternatively, the second frame layer 172a may also be formed by the dry etching process. For example, the second frame layer 172a may be formed by a process of depositing the conductive layer on the entirety of the region of the resonating part 120, a process of depositing and patterning the photo resist on the conductive layer to form a mask layer, a process of performing a dry etching for the conductor layer using the mask layer to complete the second frame layer, and a process of removing the mask layer.

In this example, the first frame layer 171a and the second frame layer 172a may be formed to have different inclined surfaces S1 and S2 by adjusting sizes and shapes of the first mask layer and the second mask layer.

Next, as illustrated in the example of FIG. 7, the photo resist may be deposited on the second frame layer 172a, a patterning may be performed by a photolithography process, and unnecessary portions of the second frame layer 172a, the first frame layer 171a, and the conductive layer 125a may be then removed, while using the patterned photo resist as the mask.

The second frame layer 172a, the first frame layer 171a, and the conductive layer 125a may all be formed of the same material. Therefore, in the present operation, the unnecessary portions of the second frame layer 172a, the first frame layer 171a, and the conductive layer 125a may be collectively removed. However, in an example in which the second frame layer 172a, the first frame layer 171a, and the conductive layer 125a are formed of different materials, the second frame layer 172a, the first frame layer 171a, and the conductive layer 125a may also be separately removed as required.

Next, the formation of second electrode 125 may be completed as illustrated in the example of FIG. 8 by significantly reducing a thickness of the conductive layer 125a disposed at an outer portion of the resonating part 120 as shown in FIG. 1.

The present operation may be performed using a photolithography process. For example, the conductive layer 125a disposed at the outer portion of the resonating part 120 is not completely removed and only the thickness thereof is reduced by adjusting an etching time, such that the second electrode 125 may be formed and the frame 170 may be completed.

Meanwhile, the present operation may be omitted as appropriate.

Next, as illustrated in the example of FIG. 9, after the piezoelectric layer 123 is partially removed, the connection electrodes 180 and 190 may be formed.

For example, the piezoelectric layer 123 may be removed using a photolithography process.

In such an example, the first connection electrode 180 may be formed by depositing gold (Au), copper (Cu), or another similar material, such as an appropriate metal, on the first electrode 121.

Similarly, the second connection electrode 190 may be formed by depositing gold (Au), copper (Cu), or another similar material, such as an appropriate metal, on the second electrode 125.

Subsequently, after confirming characteristics of the resonating part 120 and the filter and performing a necessary frequency trimming using the connection electrodes 180 and 190, the air gap 130 may then be formed.

The air gap 130 may be formed by removing the sacrificial layer 131 illustrated in the example of FIG. 9. As a result, the formation of the acoustic resonator illustrated in the example FIG. 1 may be completed. Here, the sacrificial layer 131 may be removed by using an etching method.

In the method of manufacturing an acoustic resonator according to the example that has the configuration as described above, two frame layers are sequentially formed, such that two inclined surfaces may be formed on an inner surface of the frame. Accordingly, each of the inclined surfaces of the frame may be easily formed to have a desired angle of inclination.

Meanwhile, the acoustic resonator and the method of manufacturing the acoustic resonator according to the present disclosure are not limited to the previously mentioned examples, but may be modified in various ways to provide other examples.

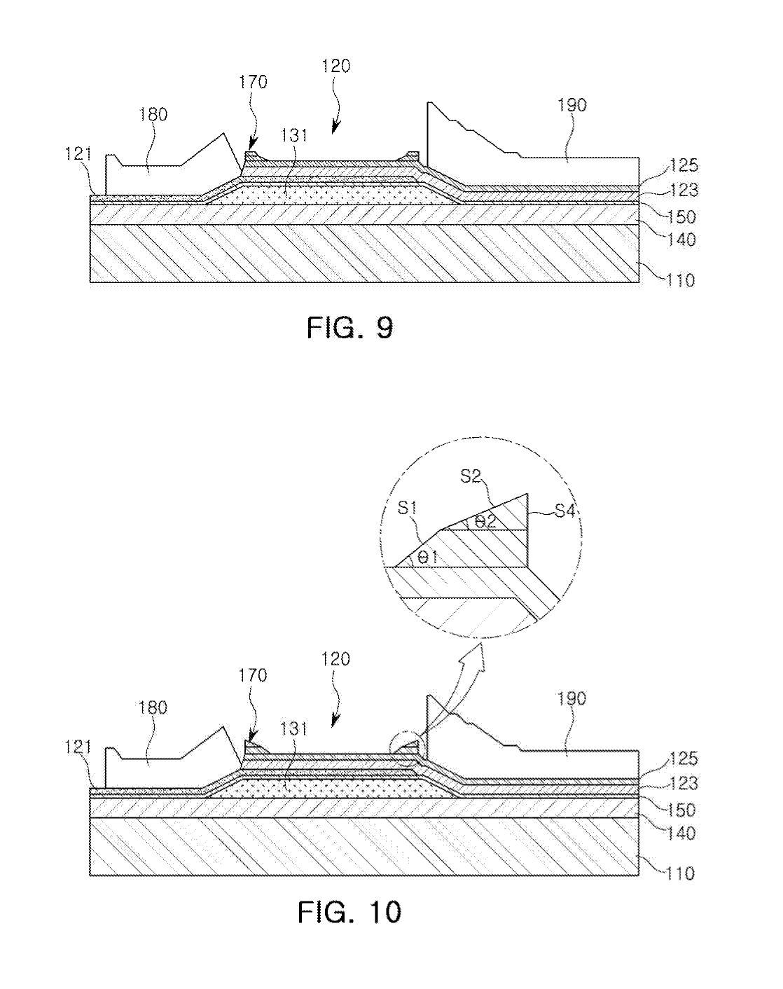

FIG. 10 is a cross-sectional view schematically illustrating an acoustic resonator according to another example.

Referring to the example of FIG. 10, the frame 170 of the acoustic resonator according to the present example may have the angle of inclination θ1 of the first inclined surface S1 be formed to be greater than the angle of inclination θ2 of the second inclined surface S2.

Furthermore, the top surface of the frame 170 may potentially be omitted, and the outer surface S4 of the frame 170 may connect the second inclined surface S2 and the second electrode 125 to each other, and may be formed in a form of vertical surface or in a form of an inclined surface.

Accordingly, the frame 170 of the acoustic resonator 100 according to the present examples may be modified in various forms as long as the inner surface of the acoustic resonator 100 is formed to have a plurality of inclined surfaces, as discussed above.

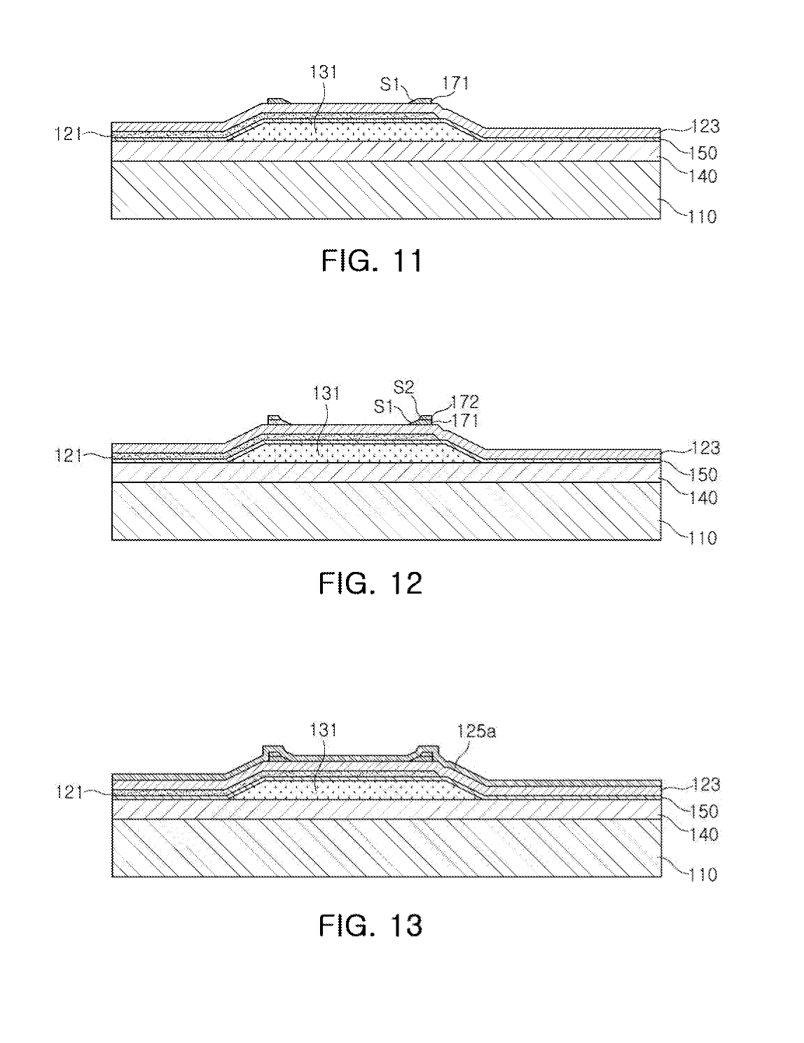

FIGS. 11 through 14 are cross-sectional views schematically illustrating a method of manufacturing an acoustic resonator according to another example.

Referring to FIGS. 11 through 14, in the method of manufacturing an acoustic resonator according to the present example, the first electrode 121 and the piezoelectric layer 123 may first be sequentially formed on the membrane layer 150 as illustrated in the example of FIG. 3.

As illustrated in the example of FIG. 11, the first frame 171 may be formed on the piezoelectric layer 123. For example, the first frame 171 may be formed by forming the conductor layer on the piezoelectric layer and then removing the unnecessary portion. Further, similarly to the example described above, the first frame 171 may be formed by the lift-off process or the dry etching process. Accordingly, the first frame 171 may have the first inclined surface S1.

As illustrated in FIG. 12, the second frame 172 may be formed on the first frame 171. Similarly to the formation of the first frame 171, the second frame 172 may be formed by the lift-off process or the dry etching process. As a result, the second frame 172 may have the second inclined surface S2.

As illustrated in the example of FIG. 13, the conductive layer 125a for forming the second electrode may then be formed. The conductive layer 125a may be formed by depositing the conductor layer on the entirety of the top surfaces of the first piezoelectric layer 123 and also the first and second frames 171 and 172. In this example, the conductive layer 125a may be formed of the same material as the first and second frames 171 and 172.

The second electrode 125 as illustrated in FIG. 14 may be completed by removing an unnecessary portion of the conductive layer 125a. For example, the removal of the conductive layer 125a may be performed using a photolithography process.

Next, the formation of the acoustic resonator 100 illustrated in the example of FIG. 1 may be completed using the process illustrated in the example of FIG. 9.

As set forth above, according to examples, because the acoustic resonator and the method of manufacturing the acoustic resonator are directed to an acoustic resonator having the Q-factor and kₜ² that are higher than the conventional acoustic resonator, the improved performance is accordingly provided.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. An acoustic resonator, comprising:
a resonating part comprising a piezoelectric layer located on a first electrode and a second electrode located on the piezoelectric layer; and
a frame located on the second electrode along an edge of the resonating part,
wherein the frame comprises an inner surface and an outer surface, and
the inner surface comprises two inclined surfaces.

2. The acoustic resonator of claim 1, wherein each of the two inclined surfaces comprises a distinct angle of inclination.

3. The acoustic resonator of claim 1, wherein the inner surface of the frame comprises a first inclined surface that extends from the second electrode, and a second inclined surface that extends from the first inclined surface.

4. The acoustic resonator of claim 3, wherein an angle of inclination of the first inclined surface is smaller than an angle of inclination of the second inclined surface.

5. The acoustic resonator of claim 3, wherein the outer surface of the frame is a vertical surface or an inclined surface.

6. The acoustic resonator of claim 3, wherein the frame further comprises a top surface that connects the second inclined surface and the outer surface to each other.

7. The acoustic resonator of claim 3, wherein the frame comprises a first frame comprising the first inclined surface and a second frame comprising the second inclined surface and located on the first frame.

8. The acoustic resonator of claim 3, wherein the frame is formed of the same material as the second electrode.

9. The acoustic resonator of claim 1, wherein the resonating part is formed on a membrane layer and spaced apart from a substrate by an air gap.

10. The acoustic resonator of claim 1, wherein the frame is formed in a ring shape along the edge of the resonating part.

11. A method of manufacturing an acoustic resonator, the method comprising:
stacking a first electrode and a piezoelectric layer on a substrate;
stacking a conductive layer on the piezoelectric layer;
forming a frame layer comprising two inclined surfaces on the conductive layer; and
completing a second electrode and a frame by patterning the frame layer and the conductive layer.

12. The method of claim 11, wherein each of the two inclined surfaces comprises a distinct angle of inclination.

13. The method of claim 11, wherein the forming of the frame layer comprises:
forming a first frame layer comprising a first inclined surface on the conductive layer; and
forming a second frame layer comprising a second inclined surface on the first frame layer.

14. The method of claim 13, wherein the forming of the frame layer comprises forming the first frame layer and the second frame layer by using a lift-off process or a dry etching process.

15. The method of claim 13, wherein the completing of the second electrode and the frame comprises:
removing portions of the conductive layer and the frame layer; and
reducing thicknesses of the conductive layer and the frame layer located on an outer portion of a resonating part.

16. The method of claim 11, further comprising:
exposing the first electrode by removing a portion of the piezoelectric layer; and
forming a connection electrode on each of the first electrode and the second electrode.

17. A method of manufacturing an acoustic resonator, the method comprising:
stacking a first electrode and a piezoelectric layer on a substrate;
forming a first frame comprising a first inclined surface on the piezoelectric layer;
forming a second frame comprising a second inclined surface on the first frame;
stacking a conductive layer on the piezoelectric layer, the first frame, and the second frame; and
performing a patterning of the conductive layer to form a second electrode and to further form the first and second frames.

18. The method of claim 17, wherein each of the first and second inclined surfaces comprises a distinct angle of inclination.
